(19) United States
(12) Patent Application Publication
(10) Pub. No.: US 2010/0067146 A1
(43) Pub. Date: Mar. 18, 2010

(54) MAGNETIC HEAD SLIDER

(75) Inventor: Osamu Kajitani, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/510,797

(22) Filed: Jul. 28, 2009

(30) Foreign Application Priority Data
Sep. 18, 2008 (JP) 2008-239561

(51) Int. Cl. G11B 5/60; G03F 7/20

(52) U.S. Cl. 360/235.4; 430/320; G9B/5.229

(57) ABSTRACT

A magnetic head slider floats by a flow of air formed by rotation of a magnetic recording medium. The magnetic head slider includes: a slider body arranged that faces a surface of the magnetic recording medium and that floats by the flow of air; an insulating layer that is provided at an end of the slider body at an outflow side of the flow of air and that includes a magnetic head element; and a projection shape part arranged at an end of the insulating layer at an outflow side of the flow of air for preventing deposition of a lubricating material deposited on the surface of the magnetic recording medium onto the magnetic head slider.

### CROSS-REFERENCE TO RELATED APPLICATION

This application is based upon and claims the benefit of priority of the prior Japanese Patent Application No. 2008-239561, filed on Sep. 18, 2008, the entire contents of which are incorporated herein by reference.

### FIELD

The embodiment discussed herein is related to a magnetic head slider.

### BACKGROUND

Along with the increase in the recording density of magnetic disk devices, the distance between a magnetic disk and a magnetic head slider in a magnetic disk device has been decreasing yearly.

Normally, the surface of a magnetic disk is coated with lubricant for preventing damage to the head and the disk caused by incidental contact with a magnetic head slider. This lubricant is a liquid, but the relative viscosity is high, so the lubricant forms a film at the surface of the magnetic disk rotating at a high speed. Further, the flow of air generated by the rotation of the magnetic disk is compressed along the flow path when passing between the magnetic head slider and the magnetic disk. Because of this, the compressed flow of air causes the magnetic head slider to float above the film of the lubricant on the magnetic disk. The distance between the floating magnetic head slider and the magnetic disk at this time is called the “flotation”.

If the flotation is reduced along with the increase in the recording density of magnetic disk devices, the vaporized lubricant will contact the surface of the magnetic head slider and condense thereby causing a phenomenon of the lubricant depositing on the surface of the magnetic head slider. The deposited drops of lubricant fall onto the medium and stick there. The contact between the deposited drops of lubricant and the head slider causes HDI (head to disk interference).

Japanese Laid-Open Patent Publication No. 2004-55127 is disclosed.

### SUMMARY

According to an aspect of the embodiment, a magnetic head slider that floats by a flow of air formed by rotation of a magnetic recording medium, the magnetic head slider comprising: a slider body arranged that faces a surface of the magnetic recording medium and that floats by the flow of air; an insulating layer that is provided at an end of the slider body at an outflow side of the flow of air and that includes a magnetic head element; and a projection shape part arranged at an end of the insulating layer at an outflow side of the flow of air for preventing deposition of a lubricating material deposited on the surface of the magnetic recording medium onto the magnetic head slider.

The object and advantages of the invention will be realized and attained by means of the components and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 illustrates an example of a configuration of a magnetic disk device;

FIG. 2 illustrates an example of a hardware configuration of a head stack assembly;

FIG. 3 illustrates an example of a printed circuit board;

FIG. 4 illustrates an overview of a magnetic head slider;

FIGS. 5A to 5C illustrate an example of the configuration of a magnetic head slider;

FIG. 6 illustrates the lubricant volume;

FIG. 7 illustrates the relationship between a drop of lubricant and the diameter of the bottom surface;

FIGS. 8A and 8B illustrate an example of the configuration of a magnetic head slider;

FIGS. 9A and 9B illustrate an example of the configuration of a magnetic head slider;

FIGS. 10A and 10B illustrate an example of the configuration of a magnetic head slider;

FIGS. 11A and 11B illustrate an example of the configuration of a magnetic head slider;

FIG. 12 illustrates an example of a method of manufacture of a magnetic head slider;

FIGS. 13A to 13D illustrate an example of a shape of the magnetic head slider in the manufacturing process;

FIG. 14 illustrates another example of a method of manufacture of a magnetic head slider;

FIGS. 15A to 15D illustrate an example of a shape of the magnetic head slider in the manufacturing process; and

FIG. 16 illustrates examples of photomasks used in manufacture of a magnetic head slider.

### DESCRIPTION OF EMBODIMENT

It is possible to prevent the deposition of a lubricant on a magnetic head slider by providing projections at the end of the magnetic head slider on the upstream side in the direction of the flow of air generated by rotation of the magnetic disk. However, even if using the projections at the inflow side of the flow of air to prevent the inflow of a part of the lubricant, lubricant will deposit on the surface of the surface of the magnetic head slider by riding on the flow of air necessary for floating the slider. Therefore, drops of lubricant will be formed on the surface of the magnetic head slider.

An embodiment of the present invention prevents the formation of drops of lubricants on the magnetic head slider.

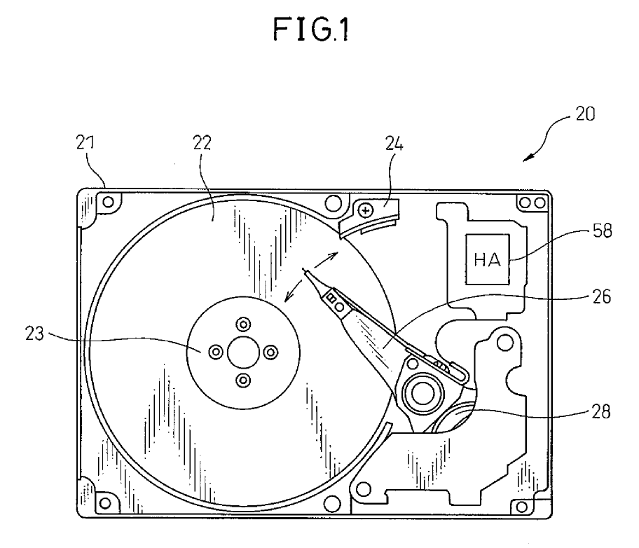

Below, an embodiment of a magnetic head slider will be explained referring to the drawings. Using FIG. 1, an example of the configuration of a magnetic disk device will be explained. The magnetic disk device functions as a device recording or reading information to and from a magnetic disk using a magnetic head. As illustrated in the drawing, a magnetic disk device 20 comprises a base 21 and a top cover (not illustrated in FIG. 1) in which are provided a magnetic disk 22, a disk holding mechanism 23, a stopper mechanism 24, a head stack assembly 26, a spindle motor 27 (not illustrated in FIG. 1), a voice coil motor 28, a printed circuit board 19 (explained later), and a head amplifier (HA) 58.

The magnetic disk 22 is a magnetic recording medium comprised of an aluminum or glass substrate on which a magnetic layer is formed. The spindle motor 27 arranged below the magnetic disk 22 is a motor for rotating the magnetic disk 22. The spindle motor 27 has a coil stator and a magnet at the inner side of the hub holding the magnetic disk 22. The disk holding mechanism 23 holds the magnetic disk 22 at the spindle motor 27 by gripping it between the hub of the spindle motor 27 and the magnetic disk 22. The stopper mechanism 24 is a mechanism having a slope for retracting a magnetic head element 4 (explained later) from the surface of the magnetic disk device 20 when the magnetic disk device 20 stops. The head stack assembly 26 is a mechanism carrying the magnetic head element 4 and turning to move the magnetic head element 4 to a predetermined position on the magnetic disk 22. The voice coil motor 28 generates a driving force with respect to the head stack assembly 26. The head amplifier 58 houses a write driver for recording data and a read amplifier for replay. It amplifies a signal read from the magnetic head element 4 connected by a printed circuit board 32 (explained later) and amplifies the current of the write signal.

FIG. 1 illustrates a magnetic disk device 20 on which a single magnetic disk 22 is mounted and a head stack assembly 26 mounting a single magnetic head element 4. However, to enable data to be recorded on both sides of the magnetic disk 22, the magnetic disk device 20 may be provided with two head stack assemblies 26 for one magnetic disk 22. In this case, the two head stack assemblies 26 may be driven by the same voice coil motor 28 simultaneously. Further, the magnetic disk device 20 may mount a plurality of magnetic disks 22.

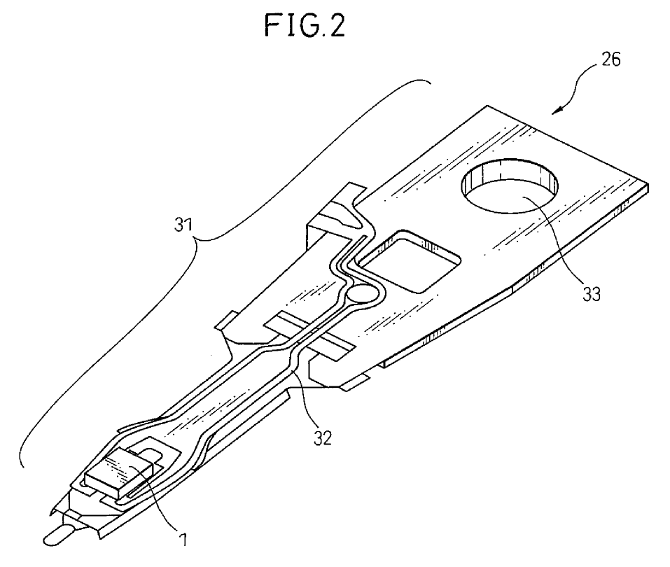

Using FIG. 2, an example of the hardware configuration of the head stack assembly will be explained. The head stack assembly 26 has a magnetic head slider 1, a printed circuit board 32, and a suspension arm 31. The magnetic head slider 1 has the magnetic head element 4, while the suspension arm 31 holds the magnetic head slider 1. Further, the magnetic head element 4 is connected by the printed circuit board 32, while the printed circuit board 32 is connected to the head amplifier 58 on the printed circuit board 19. The suspension arm 31 moves the magnetic head element 4 to the target writing or reading area on the magnetic disk 22 by the rotation operation of the voice coil motor 28. Inside a cavity 33, a bearing unit connected with the base 21 is inserted. The voice coil motor 28 is fixed to the bearing unit, whereby the driving power of the voice coil motor 28 is conveyed to the suspension arm 31.

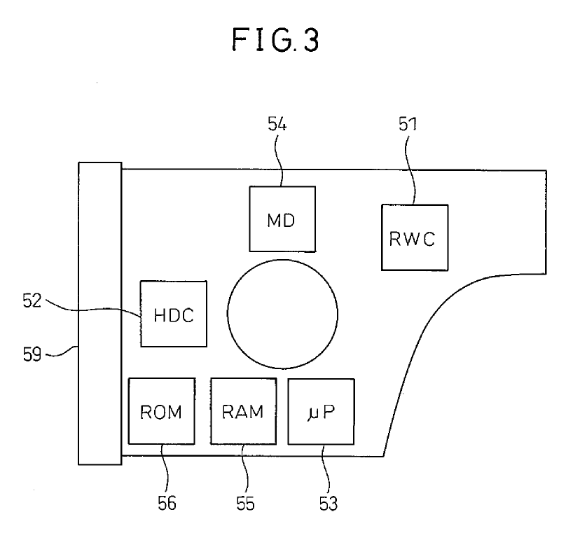

Using FIG. 3, an example of a printed circuit board will be explained. The devices provided on the printed circuit board function as control devices of the magnetic disk device. The printed circuit board is provided with a read/write circuit (RWC) 51, a hard disk controller (HDC) 52, a microprocessor (μP) 53, a motor driver (MD) 54, a random access memory (RAM) 55, a read only memory (ROM) 56, and an interface 59.

The read/write circuit 51 encodes the write data and outputs it to the head amplifier 58 illustrated in FIG. 1. Further, it detects and decodes data from signals read by the head amplifier 58. It may house a PRML (Partial Response Maximum Likelihood) signal processing circuit enabling high density recording and a circuit for extracting position information used for positioning the magnetic head element 4.

The hard disk controller 52 includes an error correction circuit and buffer control circuit. The error correction circuit performs error correction with respect to the read signal of the read/write circuit 51. The buffer control circuit controls the buffer capacity of the RAM 55. The microprocessor 53 manages and controls the entire magnetic disk device 20 and performs position control and interface control mainly for the magnetic head element 4. Further, the microprocessor 53 may include a RAM and ROM for storing programs for control processing and a logic circuit. Note that, the functions of the RAM and ROM housed in the microprocessor 53 may be replaced by a RAM 55 and ROM 56 outside of the microprocessor 53.

The motor driver 54 functions as a driver circuit of the spindle motor 27 and voice coil motor. It outputs a current to the spindle motor 27 for controlling rotation and outputs a current to the voice coil motor for loading and unloading the magnetic head slider 1. The RAM 55 is used as a buffer of data. The ROM 56 may be used for storing a control program run by the microprocessor 53. The interface 59 is a SCSI (Small Computer System Interface), ATA (AT Attachment), or other such interface. The magnetic disk device 20 may be connected through the interface 59 to a bus inside a computer in which a magnetic disk device 20 is stored.

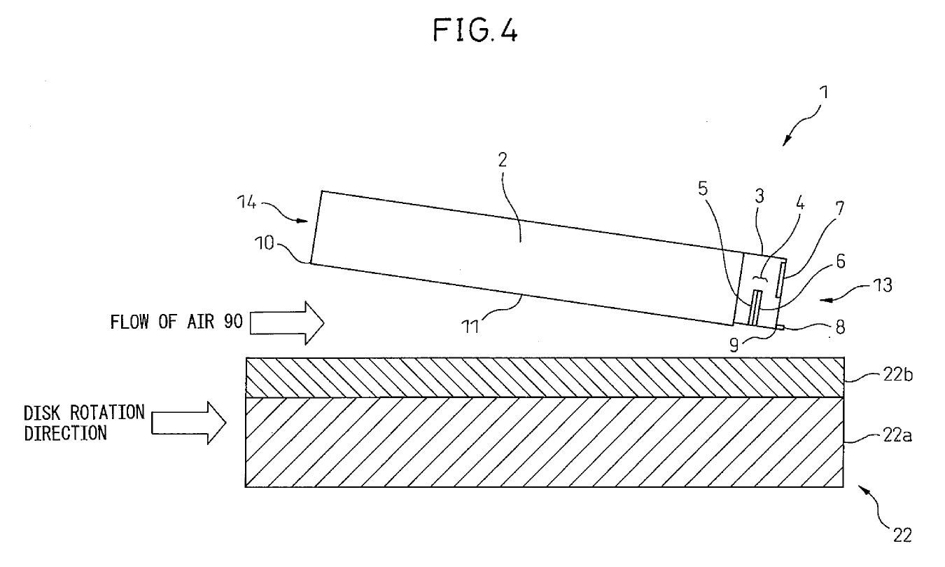

Using the FIG. 4, the magnetic head slider will be explained in brief. The magnetic disk 22 has a disk layer 22a including a substrate, an underlayer, and a protective film and a layer of a lubricant forming a lubricant layer 22b. The magnetic head slider 1 floats by to the flow of air due to the rotation of the magnetic disk 22 whereby it is arranged above the magnetic disk 22. The surface of the magnetic head slider 1 facing the surface of the magnetic disk 22, that is, an ABS (air bearing surface) 11, is provided with a shape for generating buoyancy by the flow of air 90 so as to obtain a desired flotation under various environmental conditions. Further, the magnetic head slider 1 comprises a slider body 2 and an insulating layer 3. The slider body 2 is formed by an AlTiC material (alumina-titanium carbide (Al₂O₃—TiC)). The insulating layer 3 can be formed by alumina (Al₂O₃) at the outflow end 13 of the flow of air 90 of the slider body 2. The insulating layer 3 has the magnetic head element 4. The magnetic head element 4 is formed by stacking a read element 5 including a magnetoresistive element and stacking on top of that a write element 6 including a write coil. The read element 5 is a GMR element, TMR element, or CPP element. Further, the outflow end 13 of the flow of air 90 of the insulating layer 3 is provided with a projection shape part 8 (explained later) which may be formed by alumina. Note that, the lubricant is, for example, PFPE (perfluoropolyether oil) or “Fomblin® Z” made by Solvay Solexis.

When the magnetic head slider 1 is floating, the front surface 10 of the end 14 of the ABS 11 at the inflow side of the flow of air 90 is at a position higher than the rear surface 9 of the end 13 of the insulating layer 3 at the outflow side of the flow of air 90. Accordingly, the rear surface 9 of the magnetic head slider 1 floats on the lubricant layer 22b in a state closest to the magnetic disk 22.

As illustrated, the magnetic head element 4 is mounted near the rear surface 9 close to the magnetic disk 22 when it is floating. Therefore, the magnetic head element 4 can approach the magnetic disk 22 to write a magnetic signal on the magnetic disk 22 or read a magnetic signal recorded on the magnetic disk 22. Note that, the magnetic head slider 1, for example, may be formed to a size of about a width of 1 mm, a length of 22 mm, and a thickness of 300 μm.

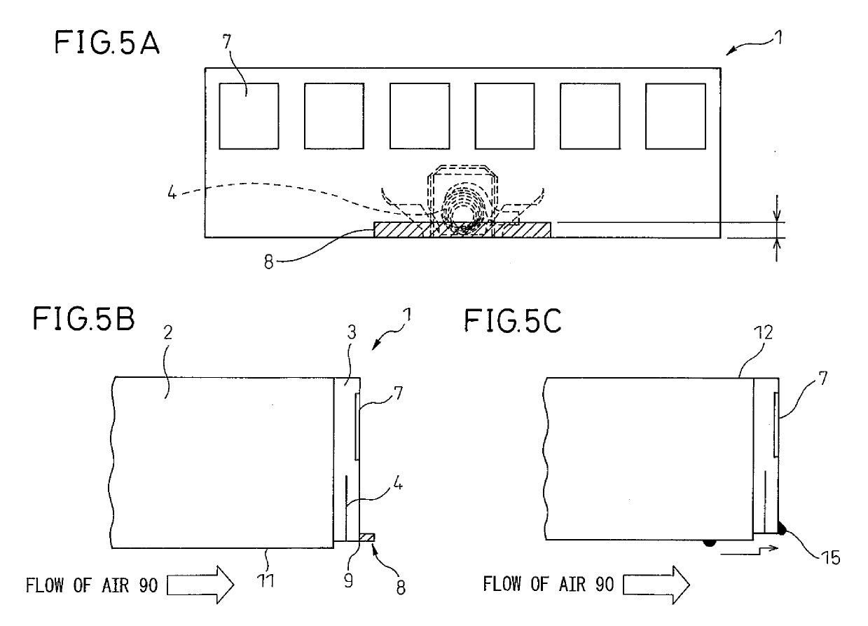

Using FIGS. 5A to 5C, an example of the configuration of a magnetic head slider will be explained. FIG. 5A is a side view of the magnetic head slider 1 seen from the outflow end side of the flow of air. FIG. 5B is a side view of the insulating layer 3 of the head slider 1 seen from a direction perpendicular to the rotational direction of the magnetic disk. FIG. 5C is a side view of a magnetic head slider 12 without a projection shape part 8 as seen from a direction perpendicular to the rotational direction of the magnetic disk. A terminal pad 7 provided at the outflow end 13 of the flow of air of the insulating layer 3 is a pad for connection to the printed circuit board 32. A signal read from the read element 5 is transmitted to the printed circuit board 32, and a write signal received from the printed circuit board 32 is transmitted to the write element 6.

As illustrated in FIG. 5C, if the vaporized lubricant contacts the surface of the magnetic head slider and condenses, the condensed lubricant will be carried by the flow of air 90 and collect at the rear surface 9 as drops of lubricant 15. The lubricant will deposit on the magnetic head slider in hemispheric shapes due to the reduction in surface area caused by the surface tension. If calculated geometrically assuming a drop of lubricant to be a sphere taking into account the effects of surface tension, the volume V of the drop of lubricant, as illustrated in the following Formula 1, may be calculated by the height h of the lubricant and the diameter r of the bottom surface of the drop of lubricant.

$$v = ( \frac{π \times h}{6} ) \times ( 3 \times {r}^{2} + {h}^{2} ) \\ h = ( \frac{r}{sin θ} ) \times ( 9 \times cos θ ) \qquad ( Formula 1 )$$

Here, the diameter of the bottom surface of the lubricant is r, and the contact angle between the lubricant and the slider surface is θ.

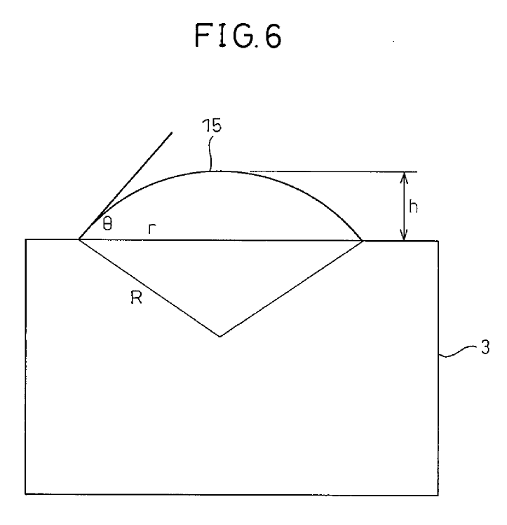

FIG. 6 illustrates the lubricant volume V calculated by the Formula 1. As illustrated in Formula 1 and FIG. 6, by reducing the bottom surface diameter r of a drop of lubricant 15 on the insulating layer 3, the volume V of the drop of lubricant 15 may be reduced. Therefore, in order to reduce the volume of the drops of lubricant 15, it is preferable to reduce the flat regions of the surface of the magnetic head slider 1 where the drops of lubricant will grow and shorten the linear distances forming the flat regions.

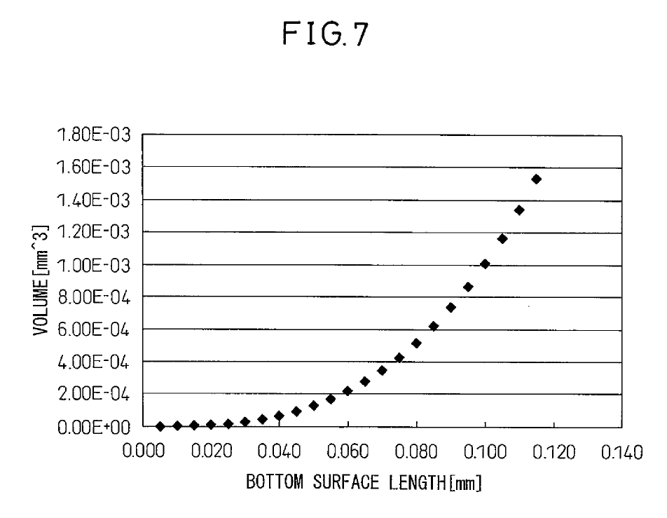

FIG. 7 is a graph illustrating the relationship between the volume of a drop of lubricant and the bottom surface diameter. This graph was created using Formula 1 assuming the contact angle θ between the lubricant and the slider surface to be 60°. As illustrated, the volume V of a drop of lubricant is proportional to the square of the bottom surface diameter.

Therefore, the magnetic head slider 1 illustrated in FIG. 5A and FIG. 5B has a projection shape part 8 on the rear surface 9 so as to prevent the formation of drops of lubricant on the magnetic head slider. By providing the projection shape part 8, the flat regions of the rear surface 9 where the bottom surface parts of the drops of lubricant grow can be reduced and the linear distances forming the flat regions can be shortened. Note that the location where the projection shape part 8 is formed is preferably near the rear surface 9 where drops of lubricant are easily formed as illustrated in FIG. 5C. However, the location where the projection shape part 8 is formed may also be on another part of the surface of the magnetic head slider 1 than near the rear surface 9 in order to prevent the formation of drops of lubricant.

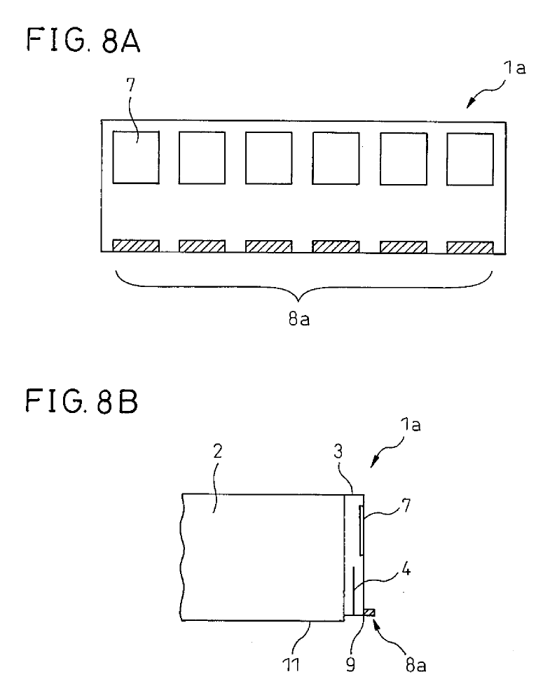

Using FIGS. 8A and 8B, an example of the configuration of the magnetic head slider will be further explained. FIG. 8A is a side view of the magnetic head slider 1a seen from the outflow end of the flow of air. FIG. 8B is a side view of the insulating layer 3 of the magnetic head slider 1a seen from a direction perpendicular to the rotational direction of the magnetic disk 22. The projection shape part 8a of the magnetic head slider 1a comprises a plurality of projection shapes arranged along the rear surface 9. Due to the plurality of projection shapes, the flat regions of the surface of the magnetic head slider at the rear surface 9 can be reduced and the linear distances can be shortened.

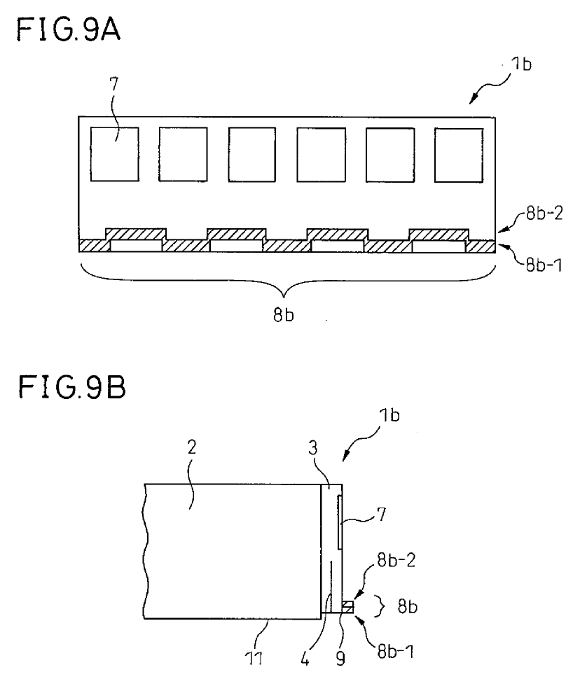

Using FIGS. 9A and 9B, another example of the configuration of a magnetic head slider will be explained. FIG. 9A is a side view of the magnetic head slider 1b seen from the outflow end of the flow of air. FIG. 9B is a side view of the insulating layer 3 of the magnetic head slider 1b seen from a direction perpendicular to the rotational direction of the magnetic disk 22. The projection shape part 8b of the magnetic head slider 1b comprises a plurality of projection shapes arranged in two lines in a vertical direction along the rear surface 9. At the projection shape part 8b, the projection shapes of the second line of line shapes 8b-2 from the rear surface 9 cover the parts with no projection shapes at the first line of line shapes 8b-1 from the rear surface 9. By forming the projection shape part 8b this way, the flat regions of the surface of the magnetic head slider at the rear part 9 are reduced and the linear distances are shortened more than the case of the line shapes 8b-1 alone.

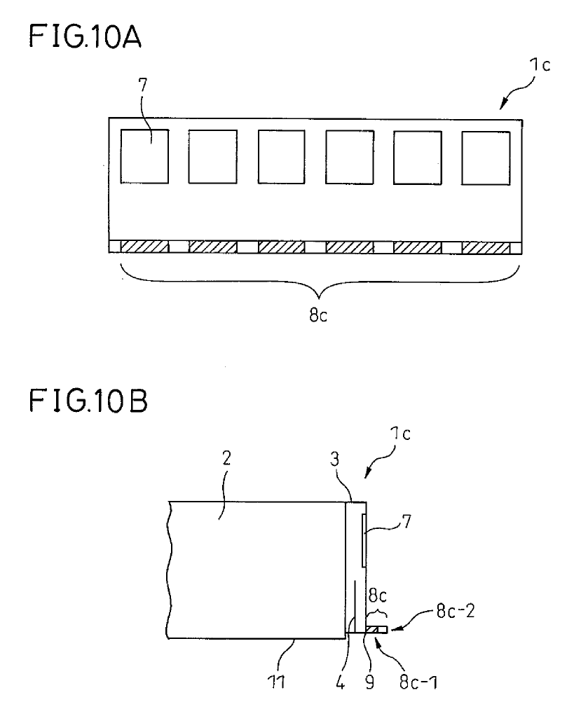

Using FIGS. 10A and 10B, a further example of the configuration of a magnetic head slider will be explained. FIG. 10A is a side view of the magnetic head slider 1c seen from the outflow end of the flow of air. FIG. 10B is a side view of the insulating layer 3 of the magnetic head slider 1c seen from the direction perpendicular to the rotational direction of the magnetic disk. A projection shape part 8c of the magnetic head slider 1c has a plurality of projection shapes arranged on a two-layer structure in the horizontal direction along the rear surface 9. The first line of line shapes 8c-1 in the horizontal direction from the rear surface 9 has no projection shapes, but the second line of lie shapes 8c-2 is formed with projection shapes. By formation in this way, the flat regions on the line shapes 8c-1 are reduced and the linear distances are shortened.

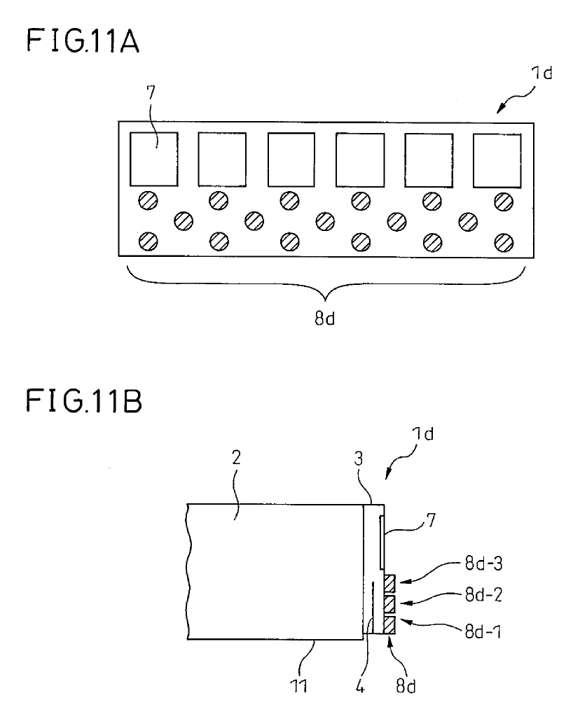

Using FIGS. 11A and 11B, a still further example of the configuration of a magnetic head slider will be further explained. FIG. 11A is a side view of a magnetic head slider 1d seen from the outflow end of the flow of air. FIG. 11B is a side view of the insulating layer 3 of the magnetic head slider 1d seen from the direction perpendicular to the rotational direction of the magnetic disk 22. A projection shape part 8d of the magnetic head slider 1d has a plurality of projection shapes arranged in three lines in the vertical direction along the rear surface 9. The projection shapes have cylindrical shapes. At the projection shape part 8d, the three line shapes 8d-1, 8d-2, and 8d-3 are arranged in a vertical direction from the rear surface 9. As illustrated, the projection shape part 8d is formed so that at the first line of the line shapes 8d-1 from the rear surface 9, the parts with no projection shapes are covered by the projection shapes of the second line of line shapes 8b-2 from the rear surface 9 and so that the third line of line shapes 8d-3 from the rear surface 9 are formed to cover the parts with no projection shapes by projection shapes at the line shapes 8d-1. By formation in this way, the flat regions of the surface of the magnetic head slider at the rear surface 9 are reduced and the linear distances are shortened more than the case of the line shapes 8d-1 alone. Note that, the illustrated projection shapes were columnar structures, however they may also be block shaped structures. Further, by forming the projection shapes tapered, the flat regions at which the bottom surface parts of the drops of lubricant grow can be further reduced.

As explained above, by providing the projection shape part on the surface of the magnetic head slider, the flat regions can be reduced and the linear parts can be shortened. Due to this, it is possible to suppress the formation of drops of lubricant on the magnetic head slider.

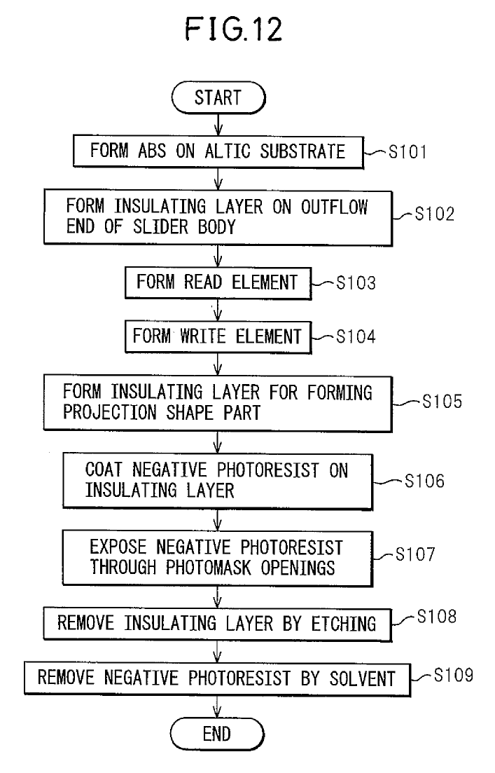

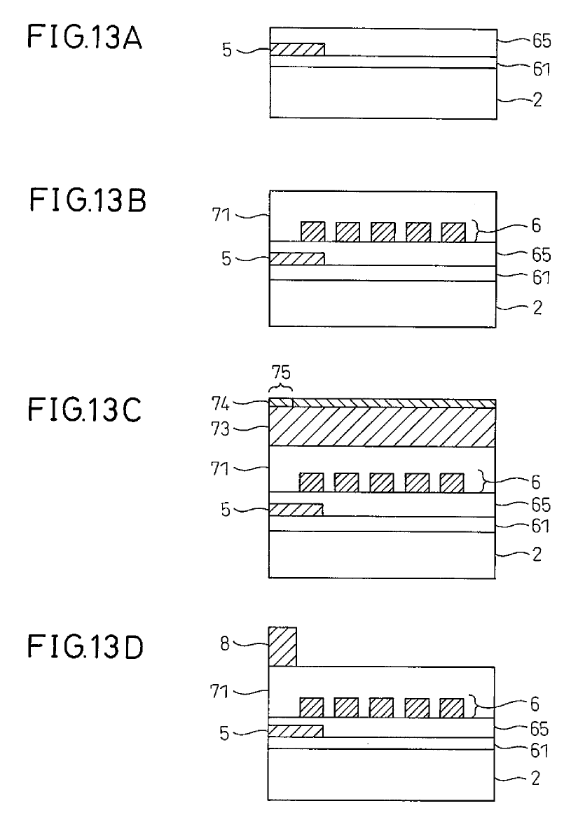

FIG. 12 is a flowchart illustrating an example of a method of manufacture of a magnetic head slider. FIGS. 13A to 13D are cross-sectional views illustrating the shape of a magnetic head slider in the manufacturing process.

Below, referring to FIG. 12 and FIGS. 13A to 13D, an example of a method of manufacture of a magnetic head slider will be explained. A magnetic head slider 1 is comprised of a slider body formed by an AlTiC substrate on which is formed an insulating layer in which a read element 5 and a write element 6 are embedded at the outflow end of the slider body. Note that magnetic head sliders are generally produced in the shape of a “slider bar”. That is, a large AlTiC substrate formed with large numbers of read elements 5 and write elements 6 is cut into a “bar” to form a plurality of sliders arranged in the horizontal direction. Here, for convenience, however, the method of manufacture will be explained illustrating a single slider.

First, an ABS 11 is formed by photolithography on an AlTiC substrate forming the slider body 2 (S101). Specifically, a photoresist is coated on the surface of the slider body 2, then a stepper is used to expose on the photoresist a pattern drawn on the photomask for forming the surface of the ABS 11. The surfaces no longer coated with the photoresist are etched, then the photoresist is removed by a solvent. By doing this, the ABS 11 for obtaining the desired flotation is formed. The photolithography in the process of production of the ABS 11 may be repeated several times to form shallow grooves, deep grooves, and other groove structures of different depths of the ABS 11.

Next, an insulating layer is formed at the end part of the substrate corresponding to the outflow end of the slider body by deposition (S102). The deposition includes the PVD (physical vapor deposition), CVD (chemical vapor deposition), etc. Specifically, as illustrated in FIG. 13A, an insulating layer 61 is formed at the outflow end of the flow of air of the slider body 2 by deposition. Next, a read element is formed (S103). Specifically, as is illustrated in FIG. 13A, a read element 5 is formed on the insulating layer 61 at the outflow end of the slider body 2 by deposition. Further, as illustrated in FIG. 13A, an insulating layer 65 is formed on the read element 5 by deposition.

Next, a write element is formed (S104). Specifically, as illustrated in FIG. 13B, a copper or other coil is formed on the insulating layer 65 by deposition to form a write element 6. Further, an insulating layer 71 is formed on the write element 6 by deposition.

Next, an insulating layer 73 for forming the projection shape part 8 is formed on the insulating layer 71 by deposition (S105). Next, a negative photoresist 74 is coated on the insulating layer 73 (S106). Further, a stepper is used to expose the negative photoresist 74 through the openings of the photomask for forming the outflow end of the projection shape part (S107). By exposed negative photoresist is dipped in a developer whereby the parts of the negative photoresist that have not been exposed are removed leaving behind the exposed parts 75 of the negative photoresist.

The insulating layer 73 below the removed negative photoresist is removed by etching (S108). The insulating layer below the exposed parts 75 of the negative photoresist is not removed by etching, so the projection shape part 8 is formed at the end of the insulating layer 71. Next, the exposed part 75 of the negative photoresist is removed by a solvent (S109) thereby ending the process of production of the magnetic head slider.

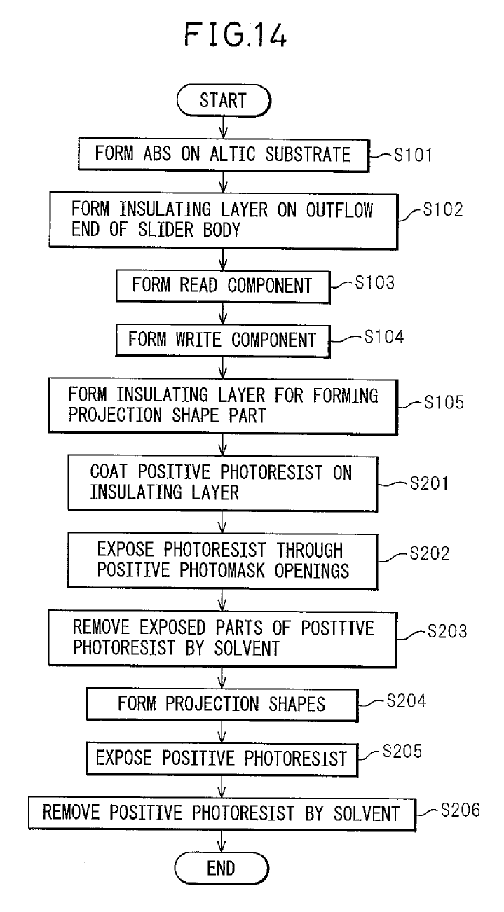

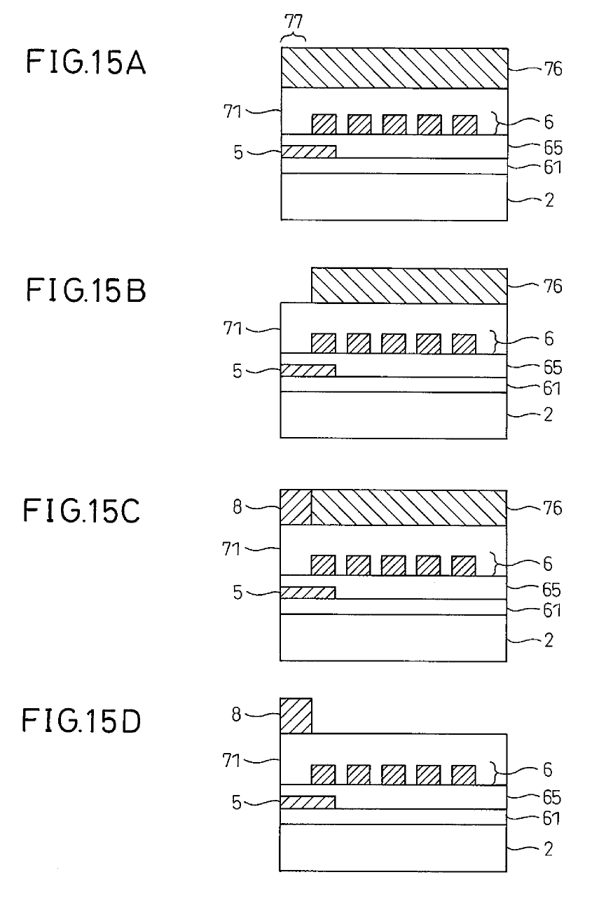

In the above method of manufacture of a magnetic head slider, a negative photoresist was used. Next, referring to FIG. 14 and FIGS. 15A to 15D, an example of a method of manufacture of a magnetic head slider using a positive photoresist will be explained. S101 to S105 illustrated in FIG. 14 are the same steps as in FIG. 12, so explanations will be omitted. In the step of coating a positive photoresist on the insulating layer 71 (S201), as illustrated in FIG. 15A, a positive photoresist 76 is coated on the insulating layer 71. Next, a stepper is used to expose the positive photoresist 76 through the openings of the photomask for forming the outflow end of the projection shape part (S202). The exposed positive photoresist 76 has an increased solubility with respect to a solvent. Therefore, as illustrated in FIG. 15B, the exposed part 77 of the positive photoresist 76 may be removed by a solvent (S203).

At the part corresponding to the exposed part of the positive photoresist removed by the solvent, an insulating layer is formed by deposition (S204). Specifically, as illustrated in FIG. 15C, an insulating layer 78 is formed at the site where the positive photoresist was removed by dissolution. Further, the entire positive photoresist 76 is exposed (S205) and the exposed positive photoresist 76 is removed by a solvent (S206), as illustrated in FIG. 15D, to form a projection shape part 8 of an insulating material at the outflow end of the insulating layer 71.

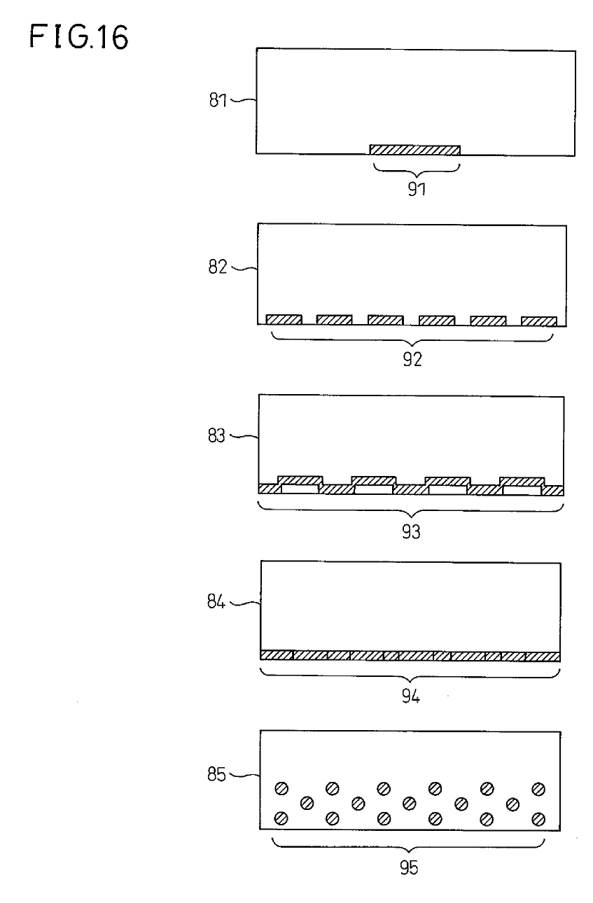

Using FIG. 16, an example of photomasks used for forming projection shapes will be explained. The photomasks 81 to 85 are formed with openings 91 to 95 for exposure by a stepper. By using these openings 91 to 95 to expose the positive photoresist or the negative photoresist, the projection shape parts 8 and 8a to 8d may be formed as explained above from the insulating layer. Note that the projection shape part 8c has a two-layer structure shape in the horizontal direction along the rear surface 9, so it is necessary to form the insulating layer to have a two-layer configuration. Therefore, the photomask 84 is used to form a projection-shaped first layer 8c-1 illustrated in FIGS. 10A and 10B by the openings 94 by the projection shape forming step (S106), further, the photomask 82 is used on the projection-shaped first layer 8c-1 to form the projection-shaped second layer 8c-2.

All examples and conditional language recited herein are intended for pedagogical purposes to aid the reader in understanding the invention and the concepts contributed by the inventor to further the art and are to be construed as being without limitation to such specifically recited examples and conditions, nor does the organization of such examples in the specification relate to a showing of superiority and inferiority of the invention. Although the embodiments of the present invention have been described in detail, it should be understood that various changes, substitutions, and alterations could be made hereto without departing from the spirit and scope of the invention.

What is claimed is:

1. A magnetic head slider that floats by a flow of air formed by rotation of a magnetic recording medium, the magnetic head slider comprising:
a slider body arranged that faces a surface of the magnetic recording medium and that floats by the flow of air;
an insulating layer that is provided at an end of the slider body at an outflow side of the flow of air and that includes a magnetic head element; and
a projection shape part arranged at an end of the insulating layer at an outflow side of the flow of air for preventing deposition of a lubricating material deposited on the surface of the magnetic recording medium onto the magnetic head slider.

2. The magnetic head slider according to claim 1, wherein the projection shape part comprises shapes that extends from the end of the insulating layer at an outflow side of the flow of air in the horizontal direction.

3. The magnetic head slider according to claim 1, wherein the projection shape part comprises a plurality of projection shapes provided spaced from each other.

4. The magnetic head slider according to claim 1, wherein the projection shape part comprises a plurality of projection shapes provided spaced from each other from the end of the insulating layer at an outflow side of the flow of air in the vertical direction.

5. A magnetic disk device that has a suspension arm having a magnetic head slider, a motor that rotates a magnetic recording medium, a motor driving the suspension arm, and a control device, wherein the magnetic head slider comprises:
a slider body arranged facing a surface of the magnetic recording medium and floating by the flow of air;
an insulating layer that is provided at an end of the slider body at an outflow side of the flow of air and that includes a magnetic head element; and
a projection shape part arranged at an end of the insulating layer at an outflow side of the flow of air for preventing deposition of a lubricating material deposited on the surface of the magnetic recording medium onto the magnetic head slider.

6. The magnetic disk device according to claim 5, wherein the projection shape part comprises shapes that extends from the end of the insulating layer at an outflow side of the flow of air in the horizontal direction.

7. The magnetic disk device according to claim 5, wherein the projection shape part comprises a plurality of projection shapes provided spaced from each other.

8. The magnetic disk device according to claim 5, wherein the projection shape part comprises a plurality of projection shapes provided spaced from each other from the end of the insulating layer at an outflow side of the flow of air in the vertical direction.

9. A method of production of a magnetic head slider that floats by a flow of air formed by rotation of a magnetic recording medium, the method of production of a magnetic head slider comprising:
forming an insulating layer that includes a magnetic head element by deposition on an end of a slider body of a magnetic head slider at an outflow side of the flow of air;
coating a negative photoresist on the insulating layer;
using a photomask that has openings to expose parts of the negative photoresist through the opening parts,
removing the not exposed negative photoresist,
etching the insulating layer not covered by the negative photoresist to forming a projection shape part on the end of the insulating layer at the outflow side; and
removing the exposed negative photoresist.

10. The method of production of a magnetic head slider according to claim 9, wherein the projection shape part comprises shapes that extends from the end of the insulating layer at an outflow side of the flow of air in the horizontal direction.

11. The method of production of a magnetic head slider according to claim 9, wherein the projection shape part comprises a plurality of projection shapes provided spaced from each other.

12. The method of production of a magnetic head slider according to claim 9, wherein the projection shape part comprises a plurality of projection shapes provided spaced from each other from the end of the insulating layer at an outflow side of the flow of air in the vertical direction.

13. A method of production of a magnetic head slider that floats by a flow of air formed by rotation of a magnetic recording medium, the method of production of a magnetic head slider comprising:
forming an insulating layer that includes a magnetic head element by deposition on an end of a slider body of a magnetic head slider at an outflow side of the flow of air,
coating a positive photoresist on the insulating layer,
using a photomask that has openings to expose parts of the positive photoresist through the opening parts,
removing the not exposed positive photoresist,
forming a projection shape part made of an insulating material at an end of the insulating layer at the outflow side by deposition at the removed positive photoresist area, and
removing the not exposed positive photoresist.

14. The method of production of a magnetic head slider according to claim 13, wherein the projection shape part comprises shapes that extends from the end of the insulating layer at an outflow side of the flow of air in the horizontal direction.

15. The method of production of a magnetic head slider according to claim 13, wherein the projection shape part comprises a plurality of projection shapes provided spaced from each other.

16. The method of production of a magnetic head slider according to claim 13, wherein the projection shape part comprises a plurality of projection shapes provided spaced from each other from the end of the insulating layer at an outflow side of the flow of air in the vertical direction.
